(19) United States
(12) Patent Application Publication
(10) Pub. No.: US 2010/0112787 A1
(43) Pub. Date: May 6, 2010

(54) Method of manufacturing semiconductor device

(75) Inventors: Youngshin Choi, Cheonan-si (KR); Kikwon Jeong, Cheonan-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/589,675

(22) Filed: Oct. 27, 2009

(30) Foreign Application Priority Data
Nov. 6, 2008 (KR) 10-2008-0109864

(51) Int. Cl. H01L 21/78; H01L 21/268

(52) U.S. Cl. 438/462; 438/463; 438/464; 438/16; 257/E21.599; 257/E21.347

(57) ABSTRACT

A method of manufacturing a semiconductor device includes preparing a substrate having a front surface where a circuit pattern is formed and a back surface opposite to the front surface, reading information of the circuit pattern formed at the front surface of the substrate over the back surface through the substrate by an image pickup member, forming a cutting part at the back surface of the substrate, grinding the back surface to form a portion of the cutting part as a dicing line, attaching an expanding tape to the back surface where the dicing line is formed, and expanding the expanding tape to separate the substrate into a plurality of chips along the dicing line.

### CROSS-REFERENCE TO RELATED APPLICATIONS

This U.S. non-provisional patent application claims priority under 35 U.S.C §119 to Korean Patent Application No. 10-2008-0109864, filed in the Korean Intellectual Property Office on Nov. 6, 2008, the entirety of which is hereby incorporated by reference.

### BACKGROUND

1. Technical Field

The present invention relates to methods for manufacturing semiconductor devices and, more specifically, relates to a die separation method for dividing a semiconductor substrate into unit chips.

2. Description of Related Art

When semiconductor integrated circuit chips (IC chips) are formed on a wafer-level semiconductor substrate (i.e., wafer), a die separation process is performed to separate the wafer into a plurality of unit chips. The die separation process may include a mechanical wafer cutting approach using a blade or a wafer cutting approach using laser.

### SUMMARY

Embodiments of the present invention provide a method of manufacturing a semiconductor device. In some embodiments of the present invention, the method may include preparing a substrate having a front surface where a circuit pattern is formed and a back surface opposite to the front surface. An image pickup member may read information of the circuit pattern formed at the front surface of the substrate, over the back surface, through the substrate. A cutting part may be formed at the back surface of the substrate. The back surface may be ground to form a portion of the cutting part as a dicing line. An expanding tape may be attached to the back surface where the dicing line is formed. The expanding tape is expanded to separate the substrate into a plurality of chips along the dicing line.

In one embodiment, grinding the back surface comprises grinding the back surface where the cutting part is formed to a determined depth.

In one embodiment, forming a cutting part may be conducted using either one of a blade and laser.

In one embodiment, preparing a substrate further comprises forming oxide at the back surface of the substrate, and reading information of the circuit pattern formed at the front surface of the substrate comprises recognizing an align key of the front surface through the oxide.

In one embodiment, the image pickup member includes a near infrared (NIR) camera.

In one embodiment, dicing the substrate comprises pressurizing the expanding tape in a direction perpendicular to the substrate to apply a pressure in a direction horizontal to the substrate.

In one embodiment, preparing a substrate further comprises forming oxide at the back surface of the substrate, and grinding the back surface includes removing the oxide.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a flowchart illustrating a method for manufacturing a semiconductor device according to some embodiments of the present invention.

FIGS. 2A to 2E are cross-sectional views illustrating the process of manufacturing a semiconductor device according to some embodiments of the present invention.

FIG. 3 illustrates a package module including a semiconductor package according to the present invention.

FIG. 4 is a block diagram of an electronic system including a semiconductor device according to some embodiments of the present invention.

FIG. 5 is a block diagram of a memory system including a semiconductor device according to some embodiments of the present invention.

### DETAILED DESCRIPTION OF THE EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this description will be thorough and complete, and will fully convey the invention to those skilled in the art. Like numbers refer to like elements throughout.

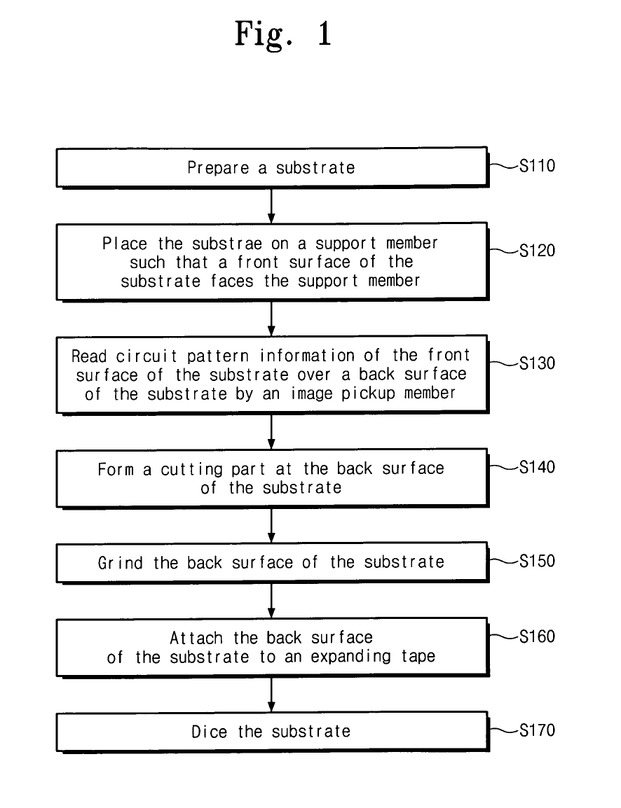

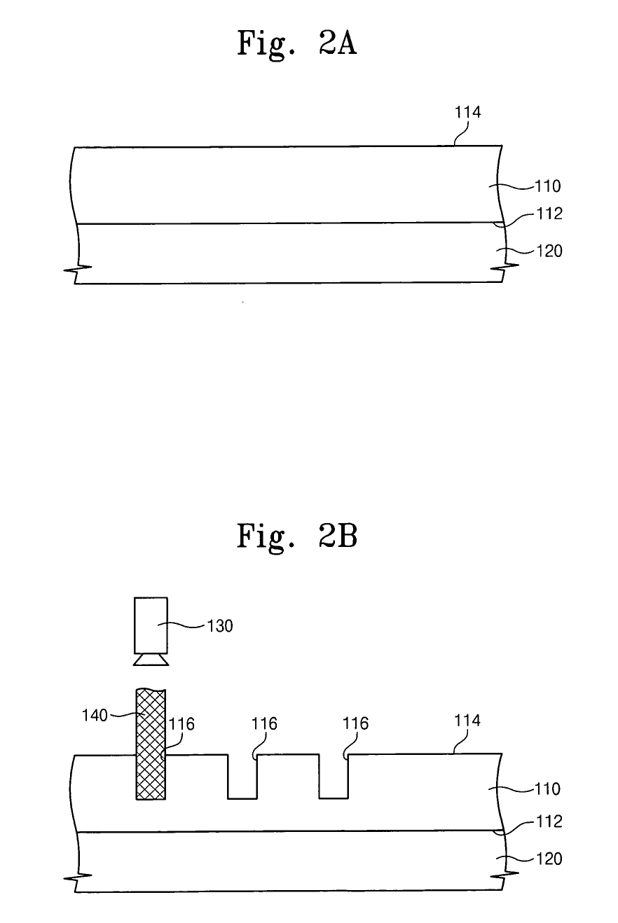

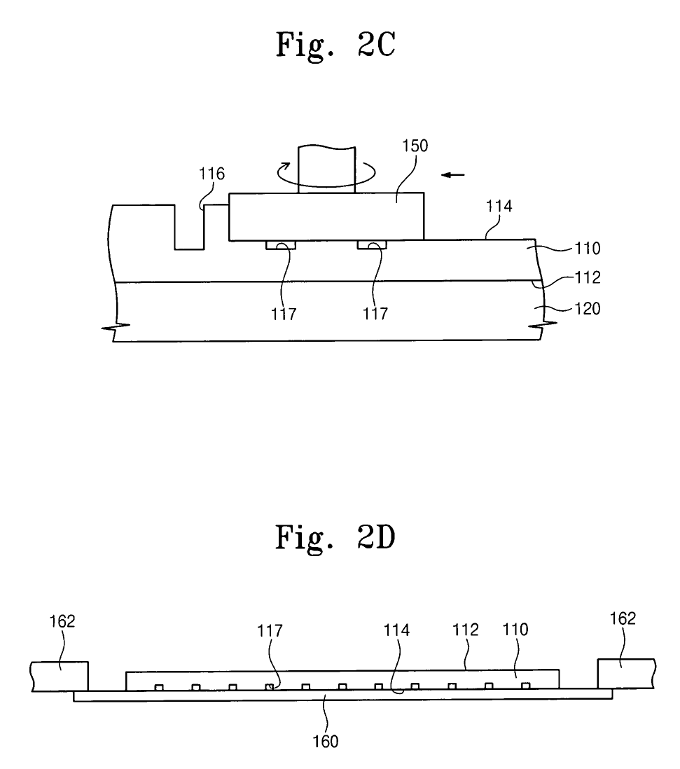

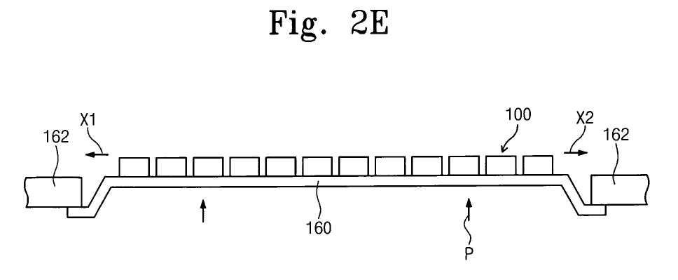

FIG. 1 is a flowchart illustrating a method for manufacturing a semiconductor device according to some embodiments of the present invention. FIGS. 2A to 2E are cross-sectional views illustrating the process of manufacturing a semiconductor device according to some embodiments of the present invention.

Referring to FIGS. 1 and 2A, a substrate 110 is prepared (S110). Preparing the substrate 110 may include preparing a substrate where electrical devices are formed. For instance, preparing the substrate 110 may include preparing a wafer-level semiconductor substrate where semiconductor integrated circuit chips (not shown) are formed. The substrate 110 may have a front surface 112 and a back surface 114 which are opposite to each other. Circuit patterns (not shown) for forming the semiconductor integrated circuit chips may be formed at the front surface 112. Preparing the substrate 110 may further include forming a thin film on the back surface 114. The thin film may include oxide and be provided to protect the back surface 114.

The substrate 110 may be placed on a support member 120 such that the front surface 112 and the support member 120 face each other (S120). The back surface 114 of the substrate 110 may be exposed to the exterior. The support member 120 may be a plate supporting the substrate 110. For instance, a surface plate may be used as the support member 120.

Referring to FIGS. 1 and 2B, an image pickup member 130 may read information of a pattern formed at the front surface 112 of the substrate 110, over the back surface 114 of the substrate 110 (S130). For example, the image pickup member 130 may be placed over the back surface 114 of the substrate 110. In order to read the pattern information of the front surface 112 of the substrate 110, the image pickup member 130 must pick up an image of the front surface 112 through the substrate 110. However, because a thin film such as oxide may be formed on the back surface 114 of the substrate 110, a typical microscope is not capable of picking up an image through the substrate 110. For this reason, the image pickup member 130 may employ an apparatus which is capable of transmitting the back surface 114 on which the thin film is formed. For instance, the image pickup member 130 may employ a near infrared camera (NIR camera). The image pickup member 130 may be disposed on the back surface 114 to recognize an align key formed on the front surface 112 even while being supported by the support member 120.

A cutting part 116 may be formed at the back surface 114 of the substrate 110 (S140). The cutting part 116 allows semiconductor integrated circuit chips formed at the substrate 110 to be separated into unit chips. In an exemplary embodiment, forming the cutting part 116 may include forming a groove at the back surface 114 of the substrate 110. The groove may have a line shape. In another exemplary embodiment, forming the cutting part 116 may include forming a groove at the back surface 114 of the substrate 110 using laser (not shown). According to the present invention, the cutting part 116 is formed at the back surface 114 of the substrate 110 to prevent damage of circuit patterns formed on the front surface 112 of the substrate 110, as compared to the case where a groove is formed on the front surface 112 of the substrate 110.

Referring to FIGS. 1 and 2C, the back surface of the substrate 110 may be ground (S150). In an exemplary embodiment, the front surface 112 of the substrate 110 is disposed to face the support member 120 and thus the back surface 114 may be exposed to the exterior. A grinder 150 may grind the entire surface of the exposed back surface 114 to a determined depth. The oxide formed at the back surface 114 may be removed partially or entirely by grinding the entire surface of the exposed back surface 114. The grinder 150 grinds the back surface 114 such that a portion of the cutting part 116 remains and thus a dicing line 117 may be formed on the back surface 114. The dicing line 117 may be a groove having a smaller depth than the cutting part 116. The dicing line 117 may be a portion separating the substrate 110 during a die separation process. When the surface grinding process is completed, the substrate 110 may be separated from the support member 120.

Referring to FIGS. 1 and 2D, the back surface 114 of the substrate 110 may be attached onto an expanding tape 160 (S160). It is noted that the orientation of the structure as shown in FIG. 2D is inverted from that of FIG. 2C. The front surface 112 of the substrate 110 may be exposed to the exterior and the dicing line 117 formed at the back surface 114 of the substrate 110 may be disposed to face the expanding tape 160. The expanding tape 160 may be provided to dice the substrate 110. The expanding tape 160 may contain an expandable and shrinkable material that may be adhered to the substrate 110. For instance, the expanding tape 160 may contain a die-attach adhesive film (DAF). An edge portion of the expanding tape 160 may be fixed by a tape support 162.

Referring to FIGS. 1 and 2E, the substrate 110 may be diced (S170). In an exemplary embodiment, a pressure P is applied to the expanding tape 160 in a direction perpendicular to a surface of the substrate 110 to expand the expanding tape 160. As the expanding tape 160 is expanded by the pressure P, the substrate 110 may receive a pressure in left and right directions X1 and X2. Accordingly, the substrate 110 may be separated into a plurality of unit chips along the dicing line 117. Through the above-described process, a plurality of semiconductor devices 100 each having the unit chip may be manufactured.

As set forth above, the substrate 110 is diced after forming the cutting part 116 and the dicing line 117 at the back surface of the substrate 110. Thus, damage of patterns formed at the front surface 112 of the substrate 110 may be suppressed during the formation of the cutting part 116 and the dicing line 117.

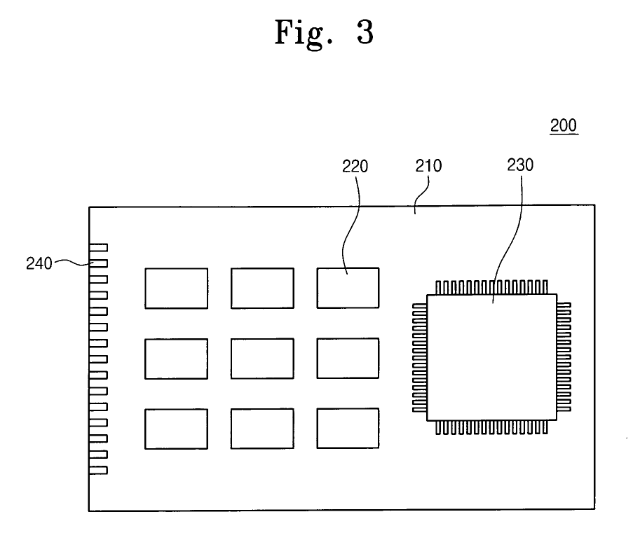

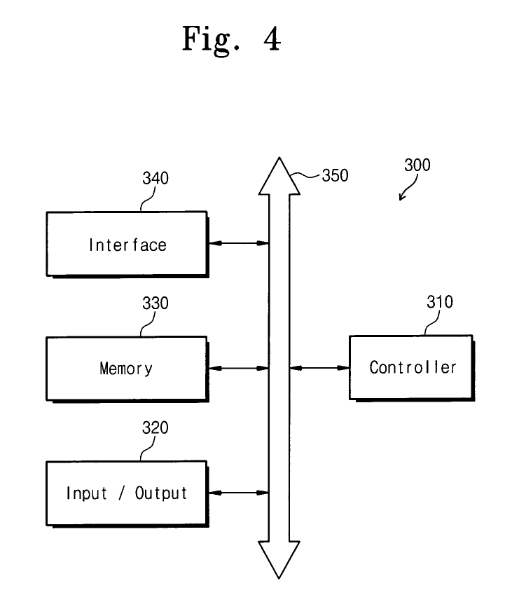

The foregoing semiconductor device and fabrication technology may be applied to various types of semiconductor devices and package modules including the same. FIG. 3 illustrates a package module 200 including a semiconductor package according to the present invention. The package module 200 may be provided as a device including one or more semiconductor integrated circuit chips 220 and/or one or more semiconductor integrated circuit chips 230 packaged by quad flat packaging (QFP). The semiconductor device 100 manufactured according to the present invention may be included in various types of separate semiconductor devices 220 and 230. The package module 200 may be formed by installing the semiconductor devices 220 and 230 at a separate semiconductor substrate 210. The package module 200 may be connected to an external electronic device through an external connector 240 disposed at one side of a semiconductor substrate 210.

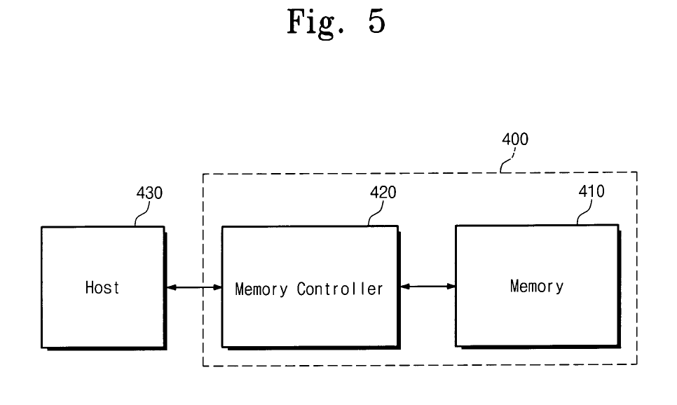

The foregoing semiconductor device and fabrication technology may be applied to an electronic system. FIG. 4 is a block diagram of an electronic system 300 including a semiconductor device according to some embodiments of the present invention. The electronic system 300 may include a controller 310, an input/output device 320, and a memory device 330. The controller 310, the input/output device 320, and the memory device 330 may be connected via a bus 350. The bus 350 may be a path through which data are delivered. As at least one microprocessor, the controller 310 may include at least one selected from the group consisting of, for instance, a digital signal processor, a microcontroller, and logic devices which are capable of performing similar functions thereto. The controller 310 and the memory device 330 may include a semiconductor device 100 manufactured by the method according to the present invention. The input/output device 320 may include at least one selected from the group consisting of a keypad, a keyboard, and a display device. The memory device 330 is a data storage device, which may store data and/or commands executed by the controller 310. The memory device 330 may include a volatile memory device and/or a nonvolatile memory device. Alternatively, the memory device 330 may include a flash memory. For instance, a flash memory device adopting the technology according to the present invention may be mounted at a mobile device or a data processing system such as a desktop computer. Such a flash memory may be a solid-state disk (SSD). In this case, the electronic system 300 may stably store massive amounts of data in the flash memory system. The electronic system 300 may further include an interface 340 for transmitting data to a communication network or receiving data from the communication network. The interface 340 may be a wired interface or a wireless interface. For instance, the interface 340 may include an antenna or a wired/wireless transceiver. The electronic system 300 may further include an application chipset, a camera image processor (CIS), and/or an input/output device.

The electronic system 300 may be embodied as a mobile system, a personal computer (PC), an industrial computer or a logic system performing various functions. For instance, the mobile system may be one selected from the group consisting of a personal digital assistance (PDA), a portable computer, a web tablet, a mobile phone, a wireless phone, a laptop computer, a memory card, a digital music system, and a data transmitting/receiving system. In the case where the electronic system 300 is an apparatus which is capable of performing a wireless communication, it may be used in a communication interface protocol such as a three-generation communication system such as CDMA, GSM, NADC, E-TDMA, WCDMA, and CDMA2000.

A semiconductor device adopting the technology according to the present invention may be provided in form of a memory card. FIG. 5 is a block diagram of a memory system including a semiconductor device according to some embodiments of the present invention. Referring to FIG. 5, a memory card 400 may include a memory device 410 including a semiconductor device according to the present invention and a memory controller 420. The memory device 410 may include a nonvolatile memory device. The memory device 410 and he memory controller 420 may store data or read stored data. The memory controller 420 may control the memory device 410 to read stored data or store data in response to read/write request of a host 430.

According to the present invention, a dicing process is performed by forming a dicing line at a back surface of a semiconductor substrate to enhance efficiency of a die separation process and prevent damage of patterns formed at the substrate during the die separation process.

Although the present invention has been described in connection with the embodiments of the present invention illustrated in the accompanying drawings, it is not limited thereto. It will be apparent to those skilled in the art that various substitutions, modifications and changes may be made without departing from the scope and spirit of the invention.

What is claimed is:

1. A method of manufacturing a semiconductor device, comprising:
preparing a substrate having a front surface where a circuit pattern is formed and a back surface opposite to the front surface;
reading information of the circuit pattern formed at the front surface over the back surface through the substrate by an image pickup member;
forming a cutting part at the back surface of the substrate;
grinding the back surface to form a portion of the cutting part as a dicing line;
attaching an expanding tape to the back surface where the dicing line is formed; and
expanding the expanding tape to separate the substrate into a plurality of chips along the dicing line.

2. The method as set forth in claim 1, wherein grinding the back surface comprises grinding the back surface where the cutting part is formed to a determined depth.

3. The method as set forth in claim 1, wherein forming a cutting part may be conducted using either one of a blade and laser.

4. The method as set forth in claim 1, wherein preparing a substrate further comprises forming oxide at the back surface of the substrate, and
reading information of the circuit pattern formed at the front surface of the substrate comprises recognizing an align key of the front surface through the oxide.

5. The method as set forth in claim 1, wherein the image pickup member includes a near infrared (NIR) camera.

6. The method as set forth in claim 1, wherein dicing the substrate comprises pressurizing the expanding tape in a direction perpendicular to the substrate to apply a pressure in a direction horizontal to the substrate.

7. The method as set forth in claim 1, wherein preparing a substrate further comprises forming oxide at the back surface of the substrate, and
grinding the back surface includes removing the oxide.
